(19) United States
(12) Patent Application Publication
(10) Pub. No.: US 2003/0193816 A1
(43) Pub. Date: Oct. 16, 2003

(54) Allochromatic light emitter

(76) Inventor: Erhard Rahn, Berlin (DE)

Correspondence Address: McGLEW AND TUTTLE, P.C., SCARBOROUGH STATION, SCARBOROUGH, NY, 10510-0827, US

(21) Appl. No.: 10/410,805

(22) Filed: Apr. 10, 2003

(30) Foreign Application Priority Data
Apr. 11, 2002 (DE) 102 16 085.6

(51) Int. Cl. H01L 33/00; F21V 7/04; F21V 9/00

(52) U.S. Cl. 362/555; 362/231

(57) ABSTRACT

An allochromatic light emitter (1) including an emitter casing (2) with a light exit port (3) and further including a fluorescent element provided in the emitter casing and a controller controlling the color of the light reproduced on a target plane. The fluorescent element is formed by an LED grid (4), with the LED grid (4) having a plurality of LEDs (5), wherein the plurality of LEDs (5) is divided into no less than two LED groups (6, 6′, 6″), with the LEDs (5) of an LED group (6) emitting light of a wave length which is different from the wave length of the emitted light of another LED group (6′, 6″). The controller includes an electronic control (7) providing different LED groups (6, 6′, 6″) independently of one another with a respectively variable operating voltage (U, U′, U″). The relationships of the operating voltages (U, U′, U″) of different LED groups (6, 6′; 6″) are controlled and/or regulated in accordance with a color to be reproduced on a target plane.

### FIELD OF THE INVENTION

The present invention is concerned with an allochromatic light emitter including an emitter casing comprising a light exit port, further including a fluorescent material contained in the said casing, and means for controlling the color of the light reproduced on a target plane, and is further concerned with a process of irradiating a target plane with changing colors, and with the use of an allochromatic light emitter of the afore-mentioned type.

The term “emitter” refers to any desired lamp(s), spot light(s) or lighting fixture(s) the emitted light of which comprises a directional characteristic, i.e. assemblies that reproduce a light spot of any desired diameter.

Any item or the human eye can form the target plane.

### BACKGROUND OF THE INVENTION AND PRIOR STATE OF ART

For-example, in external illumination of buildings or irradiation of facades it is frequently desired, for artistic or architectural reasons, to use allochromatic light. In the communicative technology, the color as well as the color change of a lamp or emitter can be used for communicating information to a person.

Conventionally, it is known in the art, for generating colored light, to employ fluorescent material having respectively a color spot or tinted glasses and foils arranged in the area of the light exit port and acting as an optical filter.

For generating allochromatic light, it is conventional wisdom to use allochromatic light emitters the fluorescent material of which is emitting white light, with mechanically rotating color wheels having different color filters or foils being located in the area of the light exit port. To that effect the colors and the number thereof are predetermined by the construction of the color wheel or foil and are not readily variable. In particular, the number of colors is restricted. In addition, the mechanisms involve high mechanical efforts and are susceptible to pollution and trouble which especially applies to outer spot lights. Mechanically adjustable iris diaphragms or dichroitic color filters require a complex control mechanism involving high space and cost requirements. It is not always possible to achieve colored transitions or predetermined color spots and saturated colors.

Moreover, LEDs (Light Emitting Diodes) are known in the art. These are semi-conductor units emitting substantially monochromatic light during operation in the passage direction. The color of the light is determined by the function of electronic state density or the band structure of the semi-conductor material as used. LEDs are commercially available, for example, in red (e.g. GaAs_{0,6}P_{0,4}, 650 nm); green (e.g. GAP:N, 570 nm) and blue light colors (e.g. GaGaN:Zn, 440 nm). Higher light capacities are obtainable by N or Al or P-doped GaIn semi-conductors, with the light intensities, based on the electric power, differing in respect of LEDs of different color. In addition, the brightness response of the eye dependent on the wave length is of relevance to the human viewer so that LEDs of different color in case of an identical electric connecting power, in the majority of cases, have a substantially different brightness response.

In conclusion LED strips and arrays are known in the art that are furnished with LEDs of the same or different color. In the latter instance, the LEDs having different colors are actuated independently and alternatively. Hence, a display is obtained alternatively illuminated in one color out of a multiplicity of invariable colors substantially restricted in number.

### TECHNICAL PROBLEM UNDERLYING THE INVENTION

The technical problem underlying the invention resides in providing an allochromatic light emitter which, on the one hand, provides any desired predetermined color spots, saturated colors and continuous colored transitions in case of a color change and, on the other hand, is of a simple, low-cost and almost maintenance free construction.

### BASIC PRINCIPLES AND PREFERRED FORMS OF EMBODIMENT OF THE INVENTION

To solve the afore-described technical problem, in the practice of the invention, the fluorescent material is formed of an LED grid comprising a plurality of LEDs divided into no less than two LED groups, wherein the LEDs of one LED group emit light of a wave length differing from the wave length of the emitted light of another LED group, with the means for controlling the color including an electronic control providing different LED groups independently of one another with a given variable operating voltage, and wherein the relationships of the operating voltages of different LED groups with respect to one another are controlled and/or regulated in accordance with a color to be reproduced on a target plane.

The language “variable operating voltage” refers to a time-related fluctuating average value. Covered thereby are not only a continuous direct voltage variable in value but also timed or pulsated direct voltages of a constant value, with a variation of the time-related average value of the voltage being adjustable through the variable timed ratio or the variable pulse duration.

In the practice of the invention it is achieved that a predetermined color spectrum can be reproduced on the target plane and that, in addition, any desired continuous or discontinuous color change can be actuated within the color spectrum. Moreover, the color change can be effected within an extremely short period of time. This is achieved without requiring any mechanical means, resulting in an allochromatic light emitter which is of a simple construction requiring substantially no maintenance. Intervals of maintenance will be exclusively determined by the average operating duration of the LEDs employed. The invention is also able to provide allochromatic light emitters of a high light intensity, because, on the one hand, LEDs having light intensities of 10,000 mcd and more are commercially available and, on the other hand, a large number of LEDs can be employed.

By controlling the operating voltages of different LED groups it is also readily possible to consider varying light intensities of different LEDs and the brightness response dependent on the wave length for which purpose it will only be necessary to determine corresponding characteristics to be integrated into the control.

According to a preferred form of embodiment of the invention, three LED groups have been provided, with the LEDs of the different LED groups emitting red-colored, green-colored or blue-colored light thereby enabling substantially all colors of the visible spectrum as well as white light to be reproduced and any desired color changes with any desired transitions to be carried out.

It is preferred to uniformly arrange the LEDs of different LED groups across a grid board. For example, red-colored, green-colored and blue-colored LEDs can be arranged directly adjacent with respect to one another, preferably at the tips of an equilateral triangle. It is possible to form larger-sized LED grids out of such color triplets, thereby enabling a tight pack of all LEDs of the LED grid to be formed.

Preferably, LEDs are used that are poured into a cylindrical body having a light-emitting lens which is recommended in the event that the cylindrical axes of the LEDs of a color triplet are not precisely aligned in parallel with respect to one another but have a common point of intersection in the direction of the light emitting lens and in spaced relation hereto, thereby attaining an optimum color mix.

According to another independent form of embodiment of the invention the LEDs are embedded in an electrically insulating heat-conducting material, with the light exit port or lens of each LED protruding from the heat insulating material, thereby insuring a substantially homogenous operating temperature of all LEDs of the LED grid and, in turn, insuring a uniform light intensity of all LEDs of an LED group. In particular, this will permit to electrically connect in series sub-groups or all LEDs of an LED group, thereby substantially facilitating the layout of the board of an LED grid and requiring a simpler and less precise voltage control or regulation due to the operating voltage of a sub-group or the LED group high on account of the series connection. Virtually, marginal effects are avoided by different operating temperatures of the LEDs arranged at the edge of the LED grid, and of the inner LEDs of the LED grid, insuring a uniform and defined color reproduction.

Sealing compounds in the form of one component or dual component sealing materials polymerizing and/or cross-linking to form thermoplastic and/or elastomeric polymers are typically used as heat-conducting materials, such as, for example, modified hydrocarbon resin. The dielectric strength should be higher than 1 kV/mm. The heat conductivity at 23° C. should be higher than 0.10 W/(mK), preferably higher than 0.20 W/(mK). The temperature increase, during polymerization should be less than 40° C., preferably less than 20° C. The continuous temperature stability should be up to 85° C., preferably up to 120° C. The glass transition temperature should be lower than −40° C., preferably lower than −70° C.

The grid board may be disposed and fixed in an LED casing arranged within the emitter casing, with the said LED casing being formed of a heat-conductive material, such as metal, and with the light exit ports being clear of the said LED casing. For example, the LED casing may be of a substantially cylindrical pan shape. The grid board can be placed into the pan and be poured thereinto together with the heat-conducting material. The port of the pan can be sealed by a punched mask, with the holes thereof being in registry with the light exit ports of the LEDs. At least part of the outer wall of the LED casing may be furnished with cooling fins. Provided in the emitter casing which, in turn is furnished, on the external side, with cooling fins (closed emitter casing) or with cooling ports (open emitter casing), is a blower, for example, a circulating-air blower in a closed emitter casing.

According to another form of embodiment of the invention, the grid board or the LED casing is manually or mechanically swivable vis-à-vis the emitter casing about one axis or about two axes in orthogonal relationship with respect to one another. In the form of embodiment being mechanically, preferably electromechanically, swivable the reproduced light spot is movable along a target plane by means of the electronic control, with the emitter casing being not movable. It is especially in closed emitter casings that this embodiment involves the advantage that the adjusting mechanism and the electromechanical drive are protected against adverse environmental influences and, consequently, are substantially free of maintenance.

Moreover, the invention provides a process for irradiating a target plane with changing colors, wherein the operating voltages of the LEDs of different LED groups of an allochromatic light emitter provided by the invention are controlled in relationships defined and variable with respect to one another in accordance with a predetermined sequence of color change.

In conclusion, the invention teaches the use of an allochromatic light emitter of the type described hereinbefore for irradiating facades of buildings (externally mounted emitter), for illuminating rooms (ceiling-mounted emitters, wall-mounted emitters or bottom-mounted emitters), with a color change being actuated for informing people present in the rooms of conditions, in particular conditions of danger, for example, automatically by means of sensors connected to the electronic control, such as temperature or smoke sensors provided in the communicating mechanism (bottom-mounted emitters, wall-mounted emitters or ceiling-mounted emitters), wherein predetermined paths are indicated by actuating an associated color.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a cross-sectional view of a bottom-mounted emitter of the invention;

FIG. 2 is a side view of an externally mounted emitter of the invention;

FIG. 3 is a cross-sectional view of the article of FIG. 2;

FIG. 4 is a view of the article of FIG. 2 contained in the light exit port;

FIG. 5A is a plan view of an LED casing having a grid board;

FIG. 5B is a cross-sectional view of an LED casing having a grid board;

FIG. 6 is a schematic view showing a diagram of an electronic control; and

FIG. 7 is a diagram showing, by way of example, the wiring of various LED groups.

### DESCRIPTION OF THE PREFERRED EMBODIMENT

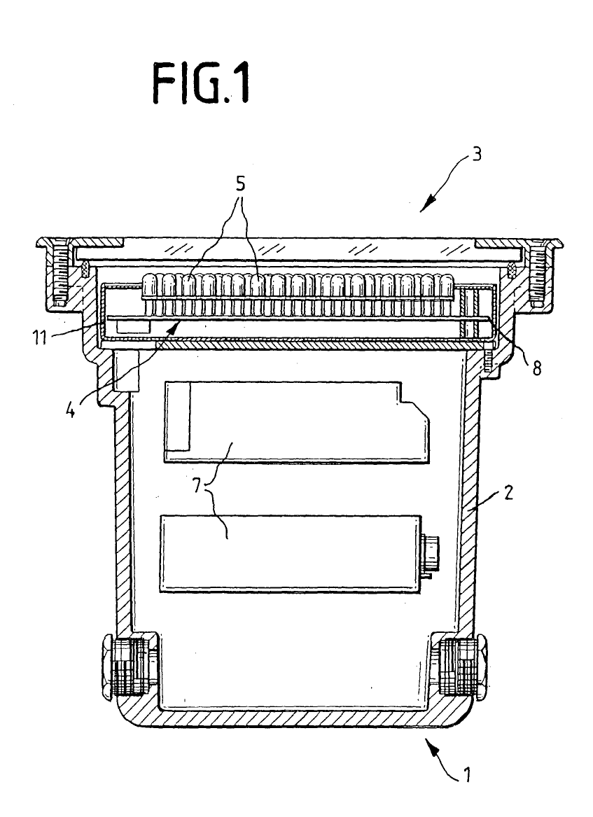

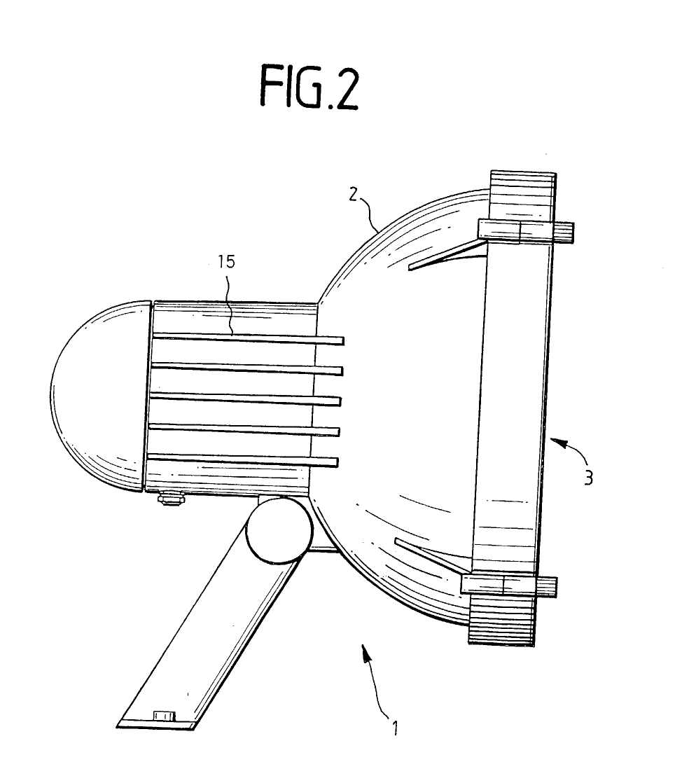

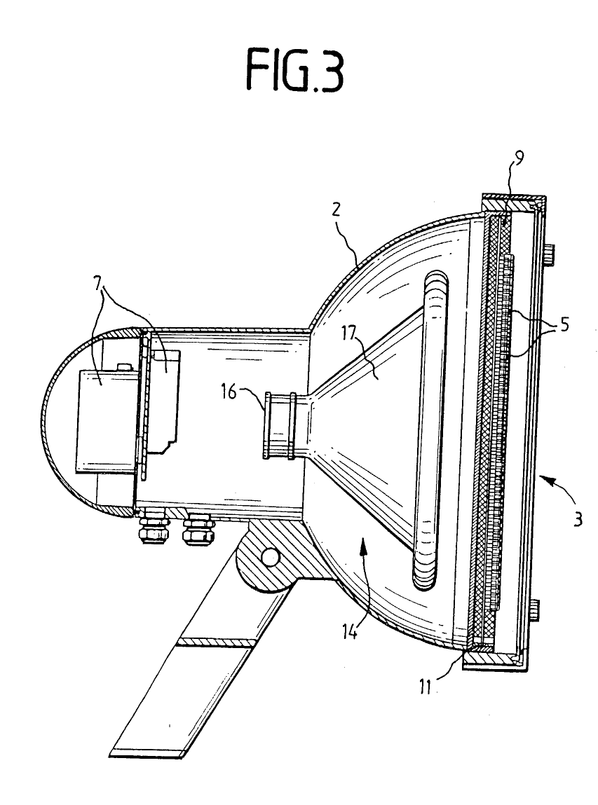

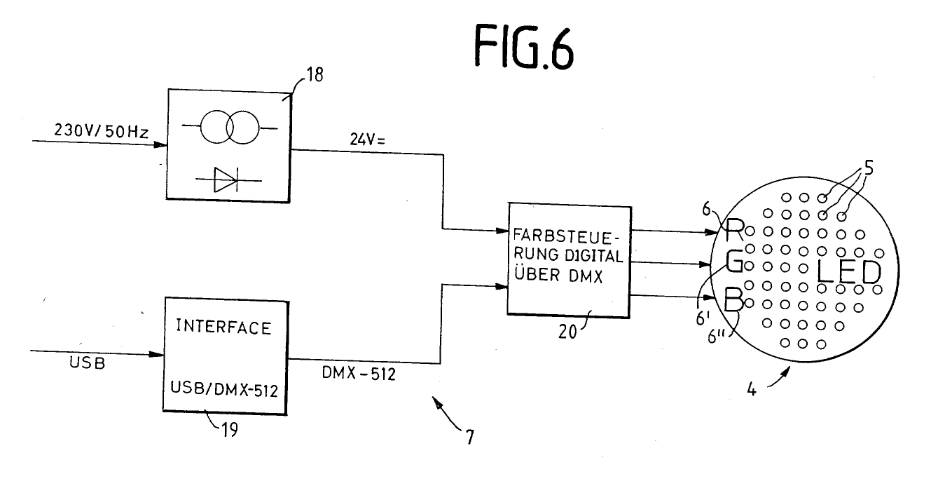

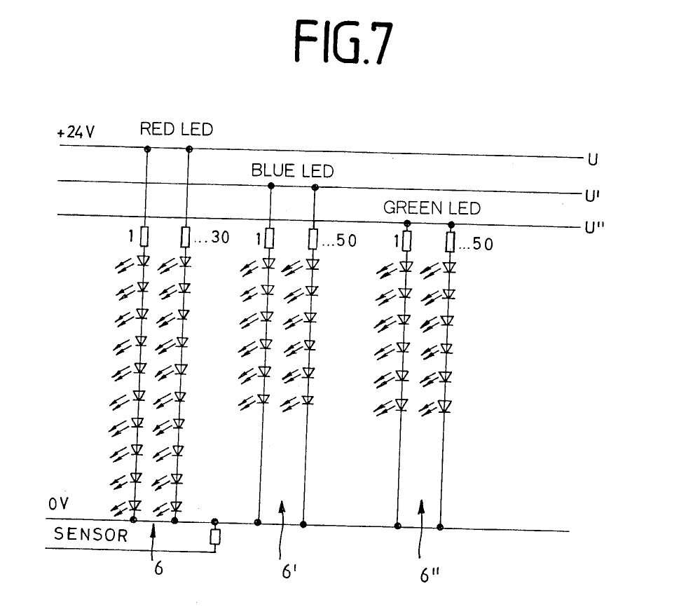

Referring to the drawings in particular, it is common to the embodiments of FIGS. 1 through 3 that they form allochromatic light emitters 1 comprising an emitter casing 2 having a light exit port 3. FIG. 1 shows a bottom-mounted light emitter, whereas FIGS. 2 and 3 illustrate an externally mounted emitter wherein cooling fins 15 are provided externally of the emitter casing 2. According to FIGS. 1 and 3 the emitter casing 2 contains an LED grid 4 comprising a plurality of LEDs 5 divided into three LED groups 6, 6′, 6″, respectively for the red, green and blue colors. By way of supplement, reference is made to FIGS. 6 and 7. Moreover, arranged in the casing 2 is an electronic control 7 providing different LED groups 6, 6′, 6″ independently of one another with a given variable operating voltage U, U′, U″. The relationships of the operating voltages U, U′, U″ of different LED groups 6, 6′, 6″ with respect to one another will be controlled and/or regulated in accordance with a color to be reproduced on the target plane, thereby effecting a defined color selection and color change, if so required. By way of supplement, reference is made to FIGS. 6 and 7 and the description to follow.

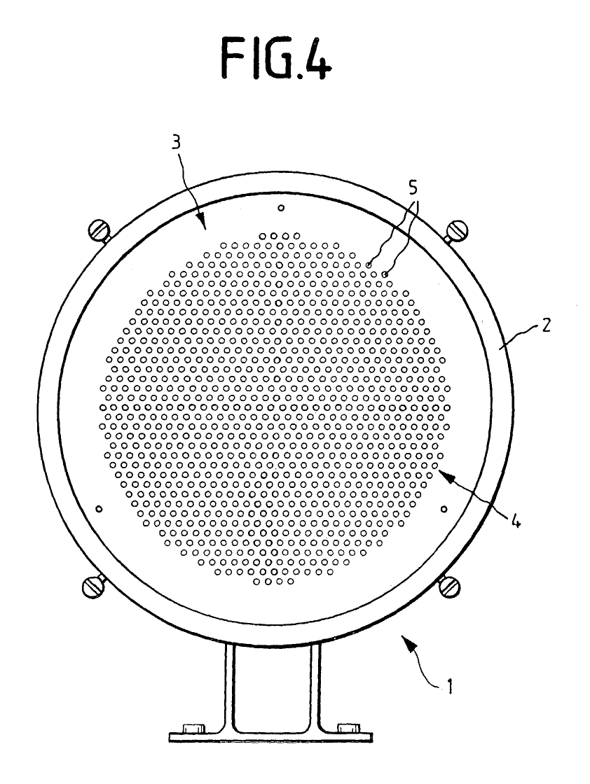

When comparing FIGS. 1, 3, 4 and 5 it will become manifest that LEDs 5 of different LED-groups 6, 6′, 6″ are uniformly distributed across a grid board 8, with a red-colored, green-colored and blue-colored LED 5 being arranged directly adjacent with respect to one another at the tips of an equilateral triangle.

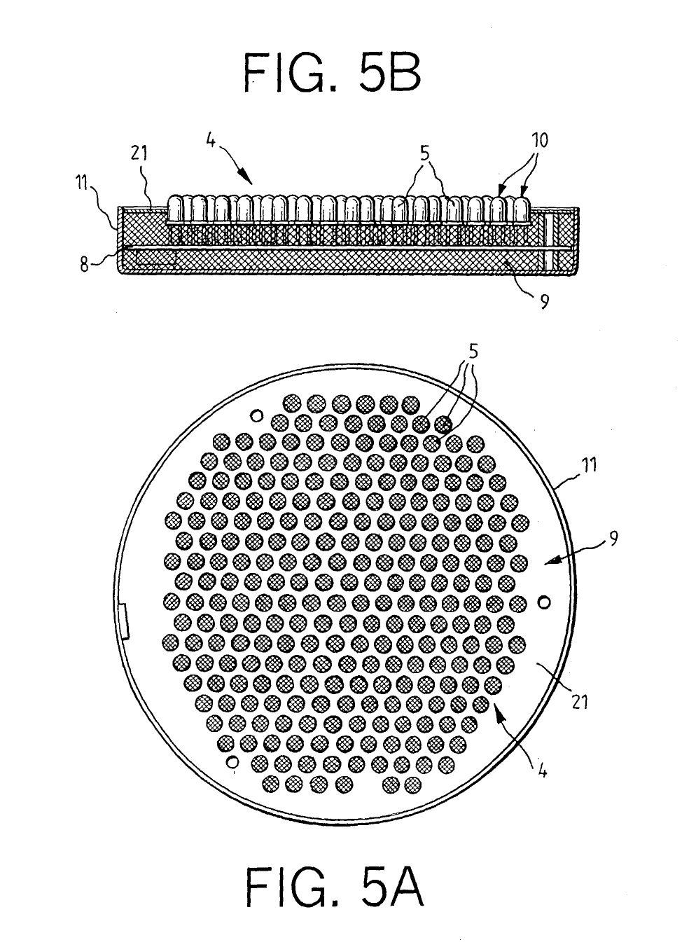

The cross-sectional view of FIG. 5 shows that the LEDs 5 are embedded in an electrically insulating heat-conducting material 9, with at least the light exit port 10 or lens 10 of each LED protruding from the heat conducting material 9. The grid board 8 is fixed within an LED casing 11 arranged in the casing 2. The LED casing 11 is made of a heat-conducting material, for example an aluminum alloy. The light exit ports 10 are clear of the LED casing 11. At least part of the outer wall of the LED casing 11 can be connected to or furnished with cooling fins (not shown) or a cooling element in thermal communication with the LED casing. To that effect it is recommended to use the outer side of the bottom of the LED casing 11. The heat-conducting material 9 is masked by a punched sheet 21.

The cross-sectional view of FIG. 3 conveys that provided in the casing 2 is a circulating-air blower 14 having a take-in port 16 and an outlet funnel 17 which is directed to the rear side of the LED casing 11. The electronic control 7 of FIG. 6 comprises a current supply unit 18, an interface 19 for connection to a control computer (not shown) and a color control interface 20 to which are connected the various LED groups 6, 6′, 6″ and which actuate the same by variable operating voltages. FIG. 7 shows that sub-groups of the LEDs 5 of an LED group 6, 6′, 6″ can be formed in which (sub-groups) a plurality of LEDs are connected in series. The sub-groups of an LED group 6, 6′, 6″, in turn, are connected in parallel. Irradiation of a target plane with changing colors is achieved in that the operating voltages of the LEDs 5 of different LED groups 6, 6′, 6″ are controlled in relationships defined and varied with respect to one another in accordance with a predetermined sequence of color change.

Provided in the light exit port 3 of the allochromatic light emitter 1 is a clear glass pane; it is, of course, also possible to provide any desired diffusing screens, lenses etc. Interesting optical three-dimensional effects will be obtained by multiple reflexion if a non-demirrored clear glass pane is used.

An LED grid is a two-dimensional assembly of LEDs, with the total number of LEDs being no less than 30, 50, 100 or 200.

While specific embodiments of the invention have been shown and described in detail to illustrate the application of the principles of the invention, it will be understood that the invention may be embodied otherwise without departing from such principles.

What is claimed is:

1. An allochromatic light emitter, comprising:
an emitter casing with a light exit port;
a fluorescent substance formed by an LED grid, said LED grid having a plurality of LEDs divided into no less than two LED groups, with the LEDs of an LED group emitting light of a wave length differing from the wave length of the emitted light of another LED group;
a controller for controlling the color of the light reproduced on a target plane with an electronic control providing various LED groups independently of one another with a respectively variable operating voltage with the relationships of the operating voltages of different LED groups controlled and/or regulated with respect to one another in accordance with a color to be reproduced on a target plane.

2. An allochromatic light emitter according to claim 1, wherein three LED groups are provided, and wherein the LEDs of the different LED groups emit red-colored, green-colored or blue-colored light.

3. An allochromatic light emitter according to claim 1, wherein the LEDs of different LED groups are uniformly distributed across a grid board.

4. An allochromatic light emitter according to claim 1, wherein red-colored, green-colored and blue-colored LEDs are arranged immediately adjacent with respect to one another, preferably on the tips of a equilateral triangle.

5. An allochromatic light emitter according to claim 1, wherein the LEDs are embedded in an electrically insulating heat-conducting substance, and wherein at least the light exit port or lens of each LED protrudes from the heat-conducting substance.

6. An allochromatic light emitter according to claim 3, wherein the grid board is arranged and fixed in an LED casing provided within the emitter casing, said LED casing being formed of a heat-conducting material including metal, and that the light exit ports are clear of the LED casing.

7. An allochromatic light emitter according to claim 6, wherein at least part of the outer wall of the LED casing is provided with cooling fins.

8. An allochromatic light emitter according to claim 1, wherein if the emitter casing is provided on an outer surface with cooling fins and or cooling ports, the interior of the emitter casing is provided with a circulating-air blower if the emitter casing is of the closed type.

9. An allochromatic light emitter according to claim 1, wherein the grid board or the LED casing vis-à-vis the emitter casing is manually or mechanically swivable about one axis or about two axes in orthogonal relationship with respect to one another.

10. A process of irradiating a target plane with changing colors, the process comprising:
providing an emitter casing with a light exit port;
providing a fluorescent substance formed by an LED grid, said LED grid having a plurality of LEDs divided into no less than two LED groups, with the LEDs of an LED group emitting light of a wave length differing from the wave length of the emitted light of another LED group; and
controlling the color of the light reproduced on a target plane with an electronic control providing various LED groups independently of one another with a respectively variable operating voltage with the relationships of the operating voltages of different LED groups controlled and/or regulated with respect to one another in accordance with a color to be reproduced on a target plane and the operating voltages of the LEDs of different LED groups of the allochromatic light emitter are controlled in relationships defined and varied with respect to one another in accordance with a predetermined color-changing sequence.

11. A process for use of an allochromatic light emitter, the process comprising:
providing an emitter casing with a light exit port;
providing a fluorescent substance formed by an LED grid, said LED grid having a plurality of LEDs divided into no less than two LED groups, with the LEDs of an LED group emitting light of a wave length differing from the wave length of the emitted light of another LED group;
controlling the color of the light reproduced on a target plane with an electronic control providing various LED groups independently of one another with a respectively variable operating voltage with the relationships of the operating voltages of different LED groups controlled and/or regulated with respect to one another in accordance with a color to be reproduced on a target plane to irradiate building facades, or for illuminating spaces, wherein a color change is actuated for informing people present in the spaces or viewing the facade of special conditions, in particular conditions of danger, or for use in the communicative technology, with predetermined paths being indicated by actuating an associated color.
